(19) United States
(12) Patent Application Publication
(10) Pub. No.: US 2016/0178686 A1
(43) Pub. Date: Jun. 23, 2016

(54) SYSTEM AND METHOD FOR IDENTIFYING AN ULTRACAPACITOR FROM A PLURALITY OF ULTRACAPACITORS

(71) Applicant: Caterpillar Inc., Peoria, IL (US)

(72) Inventors: Vijay Janardhan, Dunlap, IL (US); Hazarul Anuar, Dunlap, IL (US); Omar Bennani, Peoria, IL (US); Douglas Brown, Dunlap, IL (US); Basheer B. Qattum, Peoria, IL (US)

(73) Assignee: Caterpillar Inc., Peoria, IL (US)

(21) Appl. No.: 14/575,087

(22) Filed: Dec. 18, 2014

(51) Int. Cl. G01R 31/02; G01R 19/00

(52) U.S. Cl. CPC G01R 31/028; G01R 19/0084

(57) ABSTRACT

A source ID generation system for an energy storage system of a virtual spinning reserve coupled to power generator set includes at least one ultracapacitor having a low voltage side and a high voltage side. Each of the high voltage side and the low voltage side of the ultracapacitor includes a positive terminal, a negative terminal, a resistor input terminal, and a resistor output terminal. The source ID generation system further includes a resistor that is connected between the resistor input terminal and the resistor output terminal of the ultracapacitor. A source ID of the ultracapacitor is generated based on a voltage between the resistor input terminal and the negative terminal at the low voltage side of the ultracapacitor.

### TECHNICAL FIELD

The present disclosure relates to a method for identifying an ultracapacitor from a plurality of ultracapacitors. More particularly, the present disclosure relates to a source ID generation system for generating a source ID for each ultracapacitor in an energy storage system of a power generator set.

### BACKGROUND

Energy storage systems (ESS) associated with large power generator sets typically employs several ultracapacitors for storing electric charge. The stored electric charge may be used at various instances including, but not limited to, supplementing an output from a spinning reserve when the power output from the spinning reserve is low, or when an engine-generator set load acceptance rate is slow.

When commissioning an ESS for the first time or when reconditioning an existing ESS, each ultracapacitor in the ESS may be assigned with a source ID to facilitate identification of the ultracapacitors in the ESS. Typically, the source IDs are assigned manually to each ultracapacitor in the ESS. With manual assignment of the source IDs to each ultracapacitor, the process of commissioning or reconditioning the ESS becomes time-consuming and tedious.

U.S. Publication 2014/0062407 (hereinafter referred to as the '407 Publication) discloses a system for monitoring an ESS composed of multiple cells. However, the '407 Publication does not disclose assigning source IDs to each of the cells in the energy storage system.

### SUMMARY OF THE DISCLOSURE

In one aspect of the present disclosure, a source ID generation system for an energy storage system of a power generator set is disclosed. The energy storage system includes at least one ultracapacitor having a low voltage side and a high voltage side. Each of the high voltage side and the low voltage side of the ultracapacitor includes a positive terminal and a negative terminal. Moreover, the low voltage side of the ultracapacitor includes a resistor input terminal, and a resistor output terminal.

The source ID generation system further includes a resistor that is connected between the resistor input terminal and the resistor output terminal of the ultracapacitor. A source ID of the ultracapacitor is generated based on a voltage between the resistor input terminal and the negative terminal at the low voltage side of the ultracapacitor.

In another aspect of the present disclosure, an energy storage system for a power generator set includes at least one gateway, a plurality of ultracapacitors, and a source ID generation system. The ultracapacitors are arranged serially in the gateway. A low voltage side of the ultracapacitors includes a positive terminal and a negative terminal. Moreover, the low voltage side of each ultracapacitor includes a resistor input terminal, and a resistor output terminal.

The source ID generation system includes a resistor that is connected between the resistor input terminal and the resistor output terminal of each ultracapacitor. A voltage between the resistor input terminal and the negative terminal at the low voltage side of the ultracapacitor is indicative of the source ID of a corresponding ultracapacitor.

In another aspect of the present disclosure, a process for identifying an ultracapacitor from a plurality of serially connected ultracapacitors includes connecting a resistor to each ultracapacitor from the plurality of ultracapacitors such that at least one resistor corresponds with one ultracapacitor. The process further includes providing a rated voltage to the resistors so as to undergo a voltage drop in sequence across each of the resistors. The process further includes generating a source ID for each ultracapacitor from the plurality of serially connected ultracapacitors based on a voltage measured between a resistor input terminal and a negative terminal at a low voltage side of each ultracapacitor.

Other features and aspects of this disclosure will be apparent from the following description and the accompanying drawings.

### BRIEF DESCRIPTION OF THE DRAWINGS

FIG. 1 is a diagrammatic illustration of an exemplary power generator set having an energy storage system, in accordance with an embodiment of the present disclosure;

FIG. 2 is a diagrammatic illustration of ultracapacitors in a gateway of the energy storage system, the energy storage system employing a source ID generation system in accordance with an embodiment of the present disclosure;

FIG. 3 is a flowchart illustrating a process for identifying an ultracapacitor from a plurality of serially connected ultracapacitors in accordance with an embodiment of the present disclosure;

FIG. 4 is a low level flowchart showing a process for commissioning of the ESS in an exemplary implementation of the present disclosure; and

FIG. 5 illustrates a low level process flowchart showing a process for updating source IDs of ultracapacitors employed by the ESS, in an exemplary implementation of the present disclosure.

### DETAILED DESCRIPTION

Wherever possible, the same reference numbers will be used throughout the drawings to refer to same or like parts. Moreover, references to various elements described herein are made collectively or individually when there may be more than one element of the same type. However, such references are merely exemplary in nature. It may be noted that any reference to elements in the singular may also be construed to relate to the plural and vice-versa without limiting the scope of the disclosure to the exact number or type of such elements unless set forth explicitly in the appended claims.

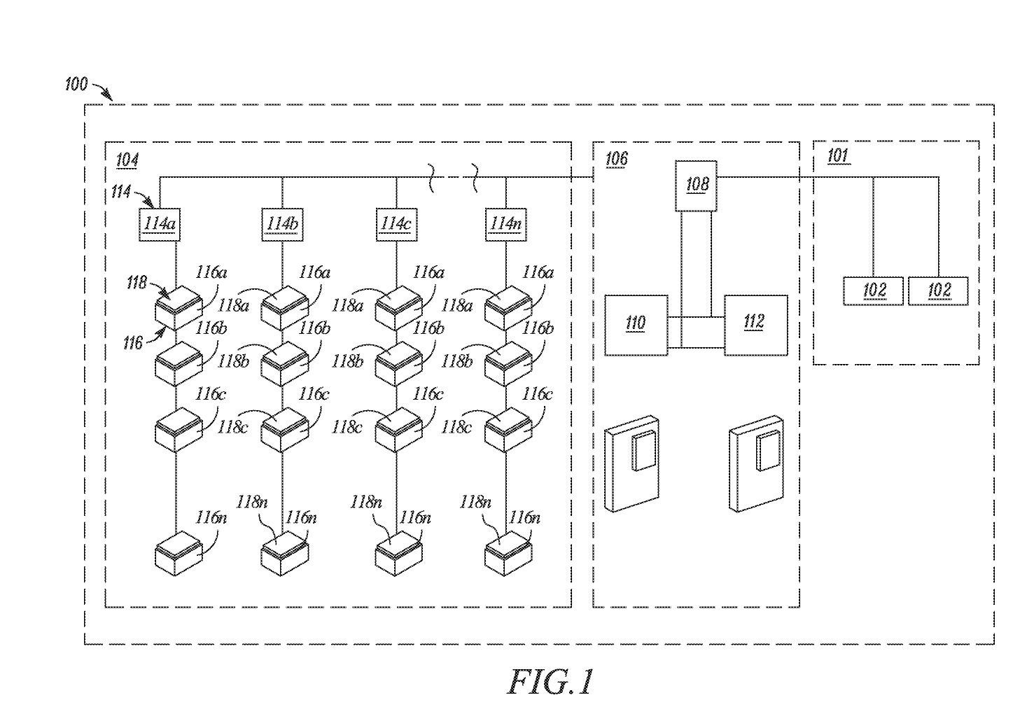

FIG. 1 shows a diagrammatic illustration of an exemplary virtual spinning reserve 100, in accordance with an embodiment of the present disclosure. The virtual spinning reserve 100 may be coupled to or provided with a power generator set 101 that may include one or more power sources 102 therein. The power sources 102 may include, but is not limited to, engines, gas turbine engines, generator sets, and other types of power sources known to one commonly skilled in the art.

In the illustrated embodiment of FIG. 1, the virtual spinning reserve 100 includes an energy storage system (ESS) 104 that is configured to store electrical energy and supply the stored electrical energy on demand. As the power generator set 101 is configured for use in heavy duty electrical applications, the demand for electrical energy is typically encountered from load on an electrical network with which the power generator set 101 is associated. In such cases, the ESS 104 may supplement the output power from the power sources 102 of the power generator set 101. In other cases, the ESS 104 may be configured for supplying electrical energy when an engine-generator set load acceptance rate is slow.

As shown in FIG. 1, the virtual spinning reserve 100 also includes a power conversion system (PCS) 106. The PCS 106 is configured to receive a supply of electrical energy from the power sources 102 and/or the ESS 104 and perform a conversion in the type or nature of electrical energy received i.e., DC-DC or DC-AC conversion as required to meet the electrical nature of the load on the power generator set 101.

Further, the PCS 106 may include at least one electrical controller 108. The electrical controller 108 is coupled with a DC-DC converter 110 and an AC-AC converter 112 for performing the required conversion to the electrical energy, i.e., DC-DC or AC-AC conversion, and meeting the nature of electrical load demand on the power generator set 101.

With continued reference to FIG. 1, the ESS 104 may include at least one gateway 114. For example, three gateways are shown in the illustrated embodiment of FIG. 1, and individually designated as 114a, 114b, 114c. Although three gateways 114a, 114b, 114c are shown in the exemplary embodiment of FIG. 1, the ESS 104 may include any number of gateways depending on specific requirements of an application.

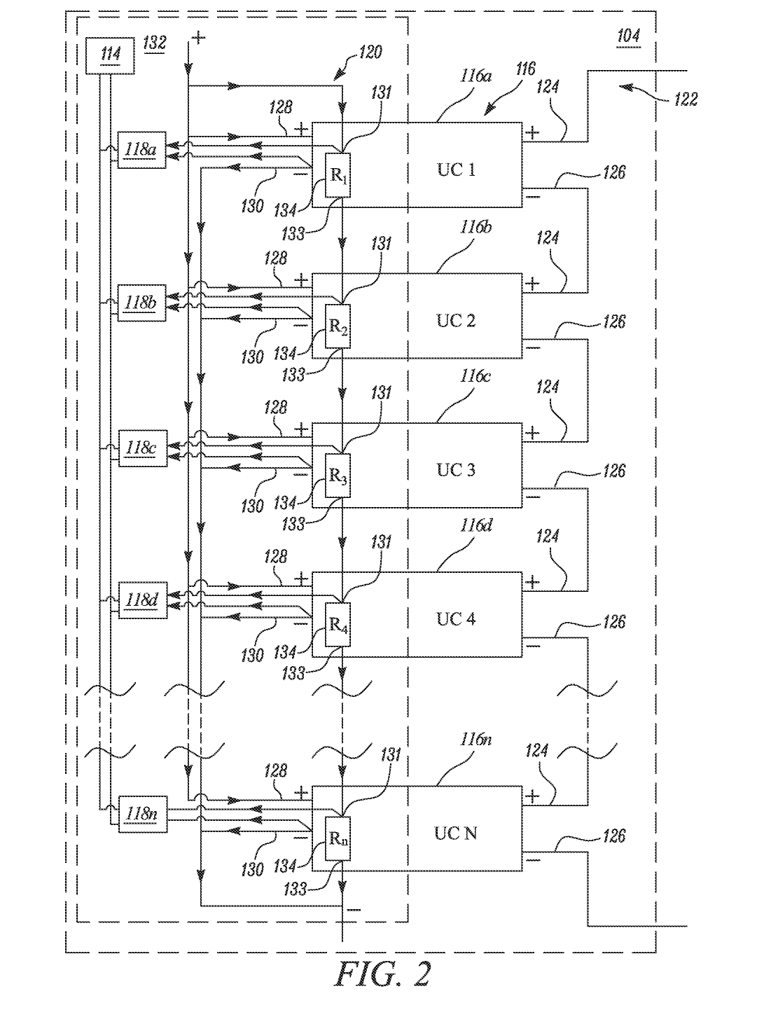

The ESS 104 further includes multiple ultracapacitors 116 (individually designated as 116a, 116b, 116c . . . 116n) that are disposed in each of the gateways 114. The ultracapacitors 116 are further designated as “UC” in the illustrated embodiment of FIG. 2. As shown, the ultracapacitors 116 from each gateway 114 are serially connected to one another. Further, each gateway 114 is provided with at least one controller 118 connected to the ultracapacitors 116 of the corresponding gateway 114. For example, ‘n’ number of controllers individually designated as 118a, 118b, 118c . . . 118n are shown in each of the gateways 114a, 114b, and 114c in the illustrated embodiment of FIG. 1.

Referring to FIG. 2, the each of the ultracapacitors 116 includes a low voltage side 120 and a high voltage side 122. The high voltage side 122 of each ultracapacitor 116 includes a positive terminal 124 and a negative terminal 126 respectively. The high voltage side 122 of the ultracapacitors 116 is typically used for powering any high voltage electrical load on the ESS 104. Similarly, the low voltage side 120 of each ultracapacitor 116 includes a positive terminal 128 and a negative terminal 130. Moreover, the the low voltage side 120 of each ultracapacitor 116 includes a resistor input terminal 131, and a resistor output terminal 133. The low voltage side 120 of the ultracapacitors 116 is typically used for utilities associated with the ultracapacitor 116 and/or the controller 118 in the corresponding gateway 114. The low voltage side 120 of the ultracapacitors 116 may also be beneficially used for various diagnostic and/or monitoring functions pertaining to the ultracapacitors 116.

The ESS 104 further includes a source ID generation system 132 which will be explained in more detail later. The source ID generation system 132 is configured for generating a source ID for each ultracapacitor 116 in the gateway 114.

The source ID generation system 132 includes a resistor 134 connected between the resistor input terminal 131 and the resistor output terminal 133 of each ultracapacitor 116. As with the ultracapacitors 116a, 116b, 116c . . . 116n, the resistors 134 are similarly designated as R₁, R₂, R₃ . . . Rₙ in the illustrated embodiment of FIG. 2 for the sake of simplicity and understanding of the present disclosure.

A source ID of each ultracapacitor 116 is generated based on a voltage between the resistor input terminal 131 and the negative terminal 130 at the low voltage side 120 of each ultracapacitor 116. It may be noted that a number of ultracapacitors in each gateway 114 is merely exemplary in nature and hence, non-limiting of this disclosure. Any number of gateways may be present in an ESS and any number of ultracapacitors and controllers may be present in each gateway of the ESS without deviating from the spirit of the present disclosure.

In various embodiments of the present disclosure, the resistors 134 associated with the ultracapacitors 116 are also connected to the controller 118. As such, the controller 118 forms part of a controller area network (CAN) that is adapted to communicate with the ultracapacitors 116 and the resistors 134 using CAN signals. The controller 118 is configured to receive signals indicative of the voltage between the resistor input terminal 131 and the negative terminal 130 at the low voltage side 120 of each ultracapacitor 116. Upon receiving the signals from each of the ultracapacitors 116 (i.e., 116a, 116b, 116c . . . 116n) and resistors 134 (i.e., R₁, R₂, R₃ . . . Rₙ), the controller 118 may generate the source ID of each ultracapacitor 116 from the received signals.

In an embodiment of the present disclosure, a sequential voltage drop across each resistor 134 (i.e., R₁, R₂, R₃ . . . Rₙ) is partly indicative of the source ID of the corresponding ultracapacitor 116 (116a, 116b, 116c . . . 116n). In an example, twenty-four ultracapacitors 116 may be present in the exemplary gateway 114 of FIG. 2, i.e., N=24, and a resistance provided by each resistor 134 (i.e., R₁, R₂, R₃ . . . Rₙ) to the flow of current may be 120 Ohms (Ω), then the voltage drop across each resistor 134 (i.e., R₁, R₂, R₃ . . . Rₙ) may be 1 Volt (V). If the voltage entering the low voltage side 120 of the ultracapacitor 116a is 24V, then the ultracapacitor 116a may be assigned a source ID “UC 1” (See FIG. 2). As the resistor 134 (i.e., R₁) associated with ultracapacitor 116a causes a voltage drop of 1V in the current flowing through it, the voltage entering the low voltage side 120 of the ultracapacitor 116b is 23V, and the ultracapacitor 116b may therefore be assigned a source ID “UC 2” (See FIG. 2).

Similarly, as the resistor (i.e., R₂) associated with ultracapacitor 116b causes a voltage drop of 1V in the current flowing through it, the voltage entering the low voltage side 120 of the ultracapacitor 116c is 22V, and the ultracapacitor 116c may therefore be assigned a source ID “UC 3” (See FIG. 2). Similarly, as the resistor (i.e., R₃) associated with ultracapacitor 116c causes a voltage drop of 1V in the current flowing through it, the voltage entering the low voltage side 120 of the ultracapacitor 116d is 21V, and the ultracapacitor 116d may therefore be assigned a source ID “UC 4” (See FIG. 2). This process of assigning source IDs is carried out for each ultracapacitor 116 in the gateway 114 until all the ultracapacitors 116 are assigned a unique source ID that corresponds with the sequential drop in voltage across the corresponding resistors 134 (i.e., R₁, R₂, R₃ . . . Rₙ).

Various embodiments disclosed herein are to be taken in the illustrative and explanatory sense, and should in no way be construed as limiting of the present disclosure. All joinder references (e.g., attached, affixed, coupled, engaged, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other.

Additionally, all numerical terms, such as, but not limited to, “first”, “second”, “third”, or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It is to be understood that individual features shown or described for one embodiment may be combined with individual features shown or described for another embodiment. The above described implementation does not in any way limit the scope of the present disclosure. Therefore, it is to be understood although some features are shown or described to illustrate the use of the present disclosure in the context of functional segments, such features may be omitted from the scope of the present disclosure without departing from the spirit of the present disclosure as defined in the appended claims.

### INDUSTRIAL APPLICABILITY

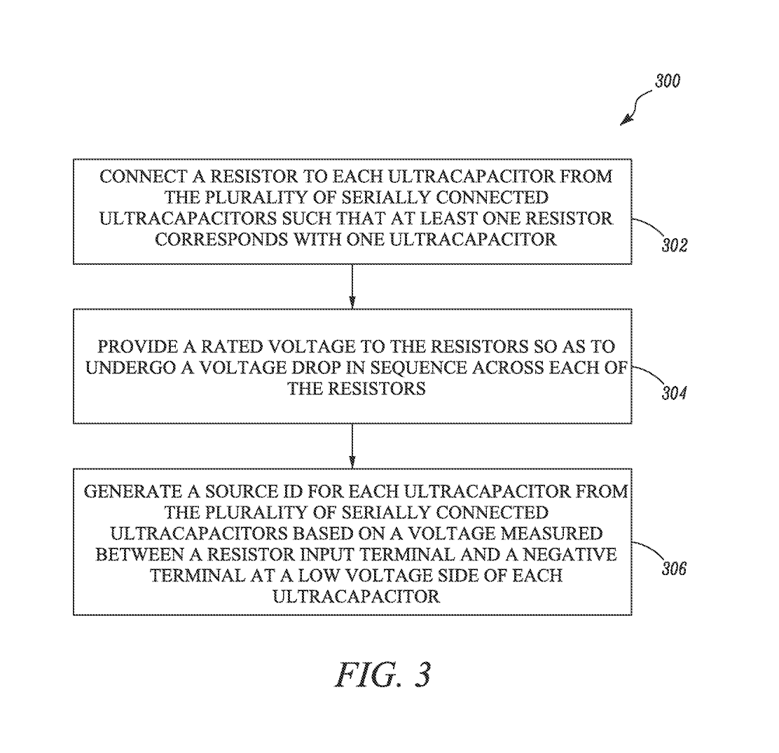

FIG. 3 illustrates a process 300 for identifying an ultracapacitor 116 from a plurality of serially connected ultracapacitors 116a, 116b, 116c . . . 116n. At block 302, the process 300 includes connecting a resistor 134 (i.e., R₁, R₂, R₃ . . . Rₙ) to each ultracapacitor 116a, 116b, 116c . . . 116n from the plurality of ultracapacitors 116 such that at least one resistor 134 corresponds with one ultracapacitor 116. As shown in FIG. 2, the resistors 134 from adjacent ultracapacitors 116 are connected in series.

At block 304, the process 300 further includes providing a rated voltage, for e.g., 24V DC, to the resistors 134 (i.e., R₁, R₂, R₃ . . . Rₙ) so as to undergo a voltage drop in sequence across each of the resistors 134 (i.e., R₁, R₂, R₃ . . . Rₙ). At block 306, the process 300 further includes generating a source ID for each ultracapacitor 116a, 116b, 116c . . . 116n from the plurality of serially connected ultracapacitors 116 based on a voltage measured between the resistor input terminal 131 and the negative terminal 130 at the low voltage side 120 of each ultracapacitor 116 (i.e., 116a, 116b, 116c . . . 116n).

In methodologies directly or indirectly set forth herein, various steps, blocks, and/or operations are described in one possible order of operation, but those skilled in the art will recognize that steps, blocks, and/or operations may be re-arranged, replaced, or eliminated without departing from the spirit and scope of the present disclosure as set forth in the claims.

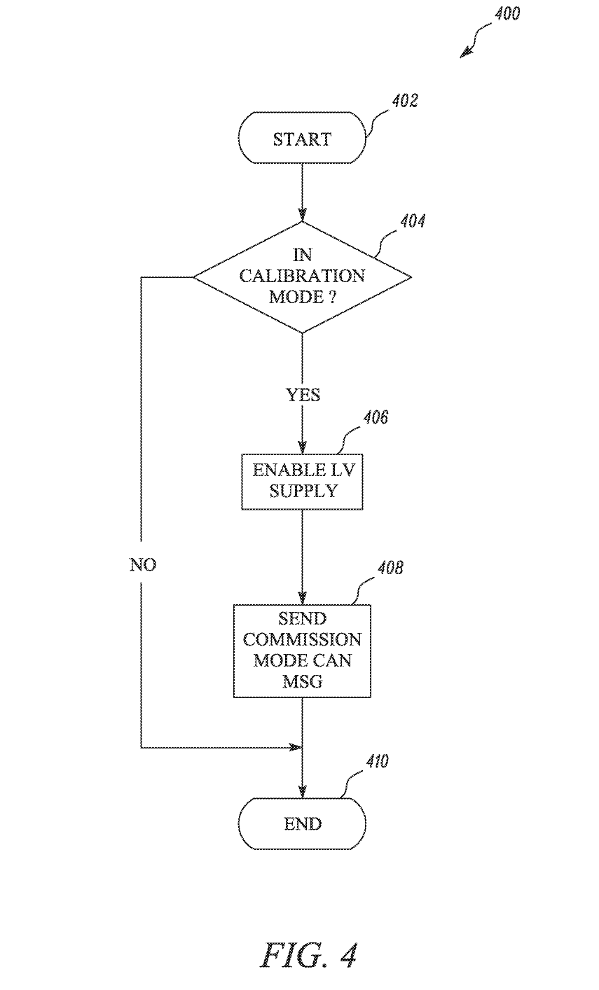

FIG. 4 illustrates a low level process flowchart 400 for commissioning of the ESS 104, the flowchart showing blocks 402-410 in an exemplary implementation of the present disclosure. While explaining the process 400 illustrated in FIG. 4, some aspects of the foregoing disclosure may be recapitulated or omitted for the purposes of better understanding of the present disclosure or for the sake of brevity in the present document. However, it should be noted that such explanation should not be construed as being limiting of this disclosure, rather the explanation pertaining to FIG. 4 should be taken merely in the illustrative and explanatory sense only.

Referring to FIG. 4, the process 400 is shown to initiate with a start block 402. At block 404, the controller 118 in each gateway 114 of the ESS 104 may be configured into a calibration mode. The calibration mode of the controller 118 disclosed in conjunction with FIG. 4 may be implemented during a commissioning of the ESS 104. If the controller 118 is configured into the calibration mode, the process 400 proceeds to block 406 where a low voltage supply is enabled such that the resistors 134 associated with the serially arranged ultracapacitors 116 receive the low voltage supply.

Upon receiving a low voltage supply, the process 400 further proceeds to block 408 where the controllers 118 send a commissioning CAN message for assigning a source ID to each of the ultracapacitors 116. As disclosed earlier herein, the controllers 118 are configured to communicate with each of the resistors 134 (i.e., R₁, R₂, R₃ . . . Rₙ) and may thereafter assign a source ID to each ultracapacitor 116a, 116b, 116c . . . 116n based on the voltage between the resistor input terminal 131 and the negative terminal 130 at the low voltage side 120 of each ultracapacitor 116 (i.e., 116a, 116b, 116c . . . 116n). The process 400 then terminates at block 410. Further, at block 404, if the controller 118 is not configured into the calibration mode, then the process 400 directly proceeds to terminate at block 410.

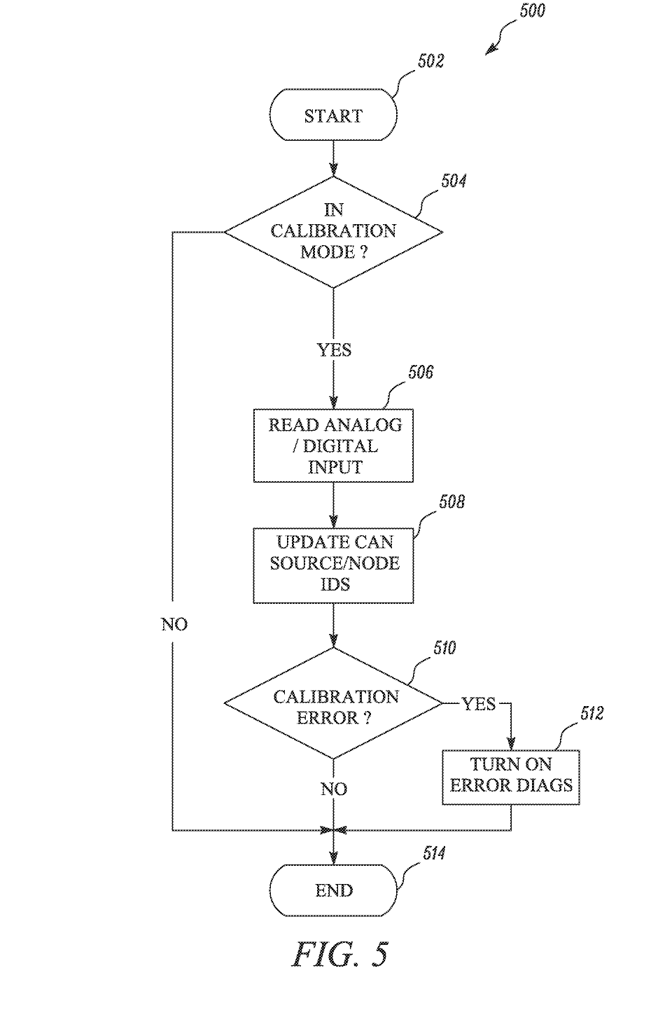

FIG. 5 illustrates a low level process flowchart 500 for updating source IDs of ultracapacitors 116 employed by the ESS 104, in an exemplary implementation of the present disclosure. While explaining the process 500 illustrated in FIG. 5, some aspects of the foregoing disclosure may be recapitulated or omitted for the purposes of better understanding of the present disclosure or for the sake of brevity in the present document. However, it should be noted that such explanation should not be construed as being limiting of this disclosure, rather the explanation pertaining to FIG. 4 should be taken merely in the illustrative and explanatory sense only.

Referring to FIG. 5, the process 500 is shown to initiate with a start block 502. At block 504, the controller 118 in each gateway 114 of the ESS 104 may be configured into a calibration mode. It may be noted that the calibration mode of the controllers 118 disclosed in conjunction with FIG. 5 may be implemented during a reconditioning of the ESS 104. If the controller 118 is configured into the calibration mode, the process 500 proceeds to block 506 where the controller 118 is further configured to receive the signals from each of the resistors 134 (i.e., R₁, R₂, R₃ . . . Rₙ) and read the signal i.e., an analog or digital input CAN message from each of the resistors 134 (i.e., R₁, R₂, R₃ . . . Rₙ).

Upon reading the analog or digital input CAN messages from each of the resistors 134 (i.e., R₁, R₂, R₃ . . . Rₙ), the process 500 proceeds to block 508 where the controller 118 updates the source IDs of the corresponding ultracapacitors 116a, 116b, 116c . . . 116n. If the controller 118 is unable to update the source ID for any ultracapacitor 116 in the gateway 114, then at block 510, the controller 118 may detect a calibration error and turn ON an error dialogue (see block 512) i.e., the controller 118 may display an error message via a suitable display device to indicate that one of the ultracapacitors 116 (116a, 116b, 116c, . . . or 116n) in the gateway 114 is non-functional. If the controller 118 is successfully able to update the source IDs for all the ultracapacitors 116a, 116b, 116c . . . 116n present in the gateway 114, then the process 500 proceeds to terminate at block 514.

Embodiments of the present disclosure have applicability for use and implementation in virtual spinning reserves where several ultracapacitors are employed. Typically, when several ultracapacitors are connected in series in an ESS, and during commissioning or reconditioning of such an ESS, it may be helpful to assign a unique source ID to each ultracapacitor in the ESS. This unique source ID to each ultracapacitor may help identify the ultracapacitors easily. With use of the resistors 134 (i.e., R₁, R₂, R₃ . . . Rₙ) and the controllers 118 to generate unique source IDs, service personnel of virtual spinning reserves may save time and effort in commissioning or reconditioning of an ESS.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

What is claimed is:

1. A source ID generation system for an energy storage system of a virtual spinning reserve coupled to a power generator set, the energy storage system having at least one ultracapacitor therein, the source ID generation system comprising:
a low voltage side of the ultracapacitor, wherein the low voltage side of the ultracapacitor comprises a positive terminal, a negative terminal, a resistor input terminal, and a resistor output terminal; and
a resistor connected between the resistor input terminal and the resistor output terminal of the ultracapacitor, wherein a source ID of the ultracapacitor is generated based on a voltage between the resistor input terminal and the negative terminal at the low voltage side of the ultracapacitor.

2. The source ID generation system of claim 1 further comprising a controller communicably coupled to the ultracapacitor and the resistor, wherein the controller is configured to receive signals indicative of the voltage between the resistor input terminal and the negative terminal at the low voltage side of the ultracapacitor.

3. The source ID generation system of claim 2, wherein the controller generates the source ID of each ultracapacitor from the received signals.

4. The source ID generation system of claim 2, wherein the controller forms part of a controller area network (CAN) that is adapted to communicate with the ultracapacitor and the resistor using CAN signals.

5. An energy storage system for a virtual spinning reserve coupled to a power generator set, the energy storage system comprising:
at least one gateway;
a plurality of ultracapacitors arranged serially in the at least one gateway;
a source ID generation system comprising:
a low voltage side of the plurality of ultracapacitors, wherein the a positive terminal, a negative terminal, a resistor input terminal, and a resistor output terminal; and
a resistor connected between the resistor input terminal and the resistor output terminal of each ultracapacitor, wherein a voltage between the resistor input terminal and the negative terminal at the low voltage side of the ultracapacitor is indicative of the source ID of a corresponding ultracapacitor.

6. The energy storage system of claim 5, wherein a sequential voltage drop across each resistor is partly indicative of the source ID of the corresponding ultracapacitor.

7. The energy storage system of claim 5, wherein the system further comprises a controller communicably coupled to each of the plurality of ultracapacitors and resistors in the gateway, wherein the controller is configured to receive signals indicative of the voltage between the resistor input terminal and the negative terminal at the low voltage side of the ultracapacitor.

8. The energy storage system of claim 7, wherein the controller generates the source ID of each ultracapacitor from the received signals.

9. The energy storage system of claim 7, wherein the controller forms part of a controller area network (CAN) that is adapted to communicate with the ultracapacitors and the associated resistors using CAN signals.

10. The energy storage system of claim 5, wherein the source ID for each ultracapacitor from the plurality of serially connected ultracapacitors is a unique source ID.

11. The energy storage system of claim 5, wherein the plurality of ultracapacitors is coupled with at least one power source.

12. A method for identifying an ultracapacitor from a plurality of serially connected ultracapacitors, the method comprising:
connecting a resistor to each ultracapacitor from the plurality of ultracapacitors such that at least one resistor corresponds with one ultracapacitor;
providing a rated voltage to the resistors so as to undergo a voltage drop in sequence across each of the resistors; and
generating a source ID for each ultracapacitor from the plurality of serially connected ultracapacitors based on a voltage measured between a resistor input terminal and a negative terminal at a low voltage side of each ultracapacitor.

13. The method of claim 12, wherein connecting the resistor to each ultracapacitor comprises connecting the resistor between a resistor input terminal and a resistor output terminal of each ultracapacitor.

14. The method of claim 12 further comprising connecting the resistors from adjacent ultracapacitors in series.

15. The method of claim 12, wherein a sequential voltage drop across each resistor is partly indicative of the source ID of the corresponding ultracapacitor.

16. The method of claim 12 further comprising providing a controller communicably coupled to each of the serially connected ultracapacitors and resistors, wherein the controller is configured to receive signals indicative of the voltage between the resistor input terminal and the negative terminal at the low voltage side of each ultracapacitor.

17. The method of claim 16, wherein the controller generates the source ID of each ultracapacitor from the received signals.

18. The method of claim 17, wherein the controller forms part of a controller area network (CAN) that is adapted to communicate with the plurality of serially connected ultracapacitors and the corresponding resistors using CAN signals.

19. The method of claim 12, wherein generating a source ID for each ultracapacitor from the plurality of serially connected ultracapacitors includes generating a unique source ID for each ultracapacitor from the plurality of serially connected ultracapacitors.

20. The method of claim 12 further including displaying the generated source IDs via a display device.
